(19) United States
(12) Patent Application Publication
(10) Pub. No.: US 2022/0059989 A1
(43) Pub. Date: Feb. 24, 2022

(54) LASER DIODE AND METHOD FOR MAKING THE SAME

(71) Applicant: XIAMEN SAN'AN OPTOELECTRONICS CO., LTD., Fujian Province (CN)

(72) Inventors: Zhibai ZHONG, Fujian (CN); Chia-en LEE, Fujian (CN); Chang-Cheng CHUO, Fujian (CN); Chen-ke HSU, Fujian (CN); Junyong KANG, Fujian (CN)

(73) Assignee: XIAMEN SAN'AN OPTOELECTRONICS CO., LTD., Fujian Province (CN)

(21) Appl. No.: 17/493,602

(22) Filed: Oct. 4, 2021

Related U.S. Application Data
(63) Continuation-in-part of application No. PCT/CN2019/088883, filed on May 28, 2019.

(51) Int. Cl. H01S 5/125; H01S 5/22; H01S 5/02

(52) U.S. Cl. CPC H01S 5/125; H01S 5/0202; H01S 5/22

(57) ABSTRACT

A laser diode includes a light-emitting stack, and a distributed Bragg reflection (DBR) cover layer in contact with the light-emitting stack. The light-emitting stack includes an N-type layer, an active layer, and a P-type layer that has a ridged member. The ridged member has an end face including a first inclined surface that inclines with respect to a top surface of the ridged member in an outward and downward direction from the top surface. A contact interface between the ridged member and the DBR cover layer includes the first inclined surface. A method for making the laser diode is also disclosed.

### CROSS-REFERENCE TO RELATED APPLICATION

This application is a bypass continuation-in-part (CIP) application of PCT International Application No. PCT/CN2019/088883, filed on May 28, 2019. The entire content of the international patent application is incorporated herein by reference.

### FIELD

The disclosure relates to a semiconductor light-emitting diode, and more particularly to a laser diode and a method for making the same.

### BACKGROUND

GaN-based light-emitting diodes (LEDs) and laser diodes are extensively researched and profusely applied in the market, especially in the fields of laser display and laser projection, such as GaN-based blue or green-colored laser diodes, which mainly has an edge-emitting ridge-waveguide structure. For a laser diode to adopt the edge-emitting ridge-waveguide structure, distributed Bragg reflection (DBR) mirrors are plated on both ends of a laser bar in order to form a Fabry-Pérot cavity that is used for resonance. Conventional Fabry-Pérot cavity surfaces are all right-angled, which results in poor coverage of the DBR mirrors on the edges of the cavity and easy breakage when under high stress. Moreover, side-plated DBR cover layers may adversely affect the eutectic structure of the laser diode, thereby affecting electrical properties of the laser diode.

### SUMMARY

Therefore, an object of the disclosure is to provide a laser diode that can alleviate at least one of the drawbacks of the prior art.

According to a first aspect of the present disclosure, there is provided a laser diode that includes:
a light-emitting stack, the light-emitting stack including an N-type layer, an active layer, and a P-type layer that has a ridged member; and
a distributed Bragg reflection (DBR) cover layer in contact with the light-emitting stack,
wherein
the ridged member has an end face including a first inclined surface that inclines with respect to a top surface of the ridged member in an outward and downward direction from the top surface, and
a contact interface between the ridged member and the DBR cover layer includes the first inclined surface.

According to a second aspect of the present disclosure, there is provided a method for making a laser diode. The method includes the steps of:

forming a light-emitting stack, the light-emitting stack having an N-type layer, an active layer and a P-type layer, the P-type layer being formed with a ridged member;

cleaving the ridged member in a direction perpendicular to a lengthwise direction of the ridged member to obtain a first inclined surface at an end face where the ridged member is cleaved; and

growing a DBR cover layer that covers the light-emitting stack, a contact interface between the DBR cover layer and the ridged member including the first inclined surface.

### BRIEF DESCRIPTION OF THE DRAWINGS

Other features and advantages of the disclosure will become apparent in the following detailed description of the embodiment(s) with reference to the accompanying drawings, of which:

FIG. 1 is a perspective view illustrating an embodiment of a laser diode according to the present disclosure, but with a DBR cover layer being omitted;

FIG. 2 is a structural schematic view illustrating a one-sided wedge-shaped laser diode according to the present disclosure;

FIG. 3 is a structural schematic view illustrating a two-sided wedge-shaped laser diode according to the present disclosure;

FIG. 4 is a schematic flow chart illustrating a method for making a laser diode according to the present disclosure;

FIG. 5 is a schematic view illustrating the relative positions of V-shaped grooves with a ridged member of the present disclosure; and

FIG. 6 is a structural schematic view of two-sided wedge-shaped laser diodes with differently shaped grooves.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

In addition, in the description of the present disclosure, the terms “outward”, “inward”, “upward”, “downward”, “top”, “bottom”, “front” are meant to indicate relative position between the elements of the disclosure, and are not meant to indicate the actual position of each of the elements in actual implementations.

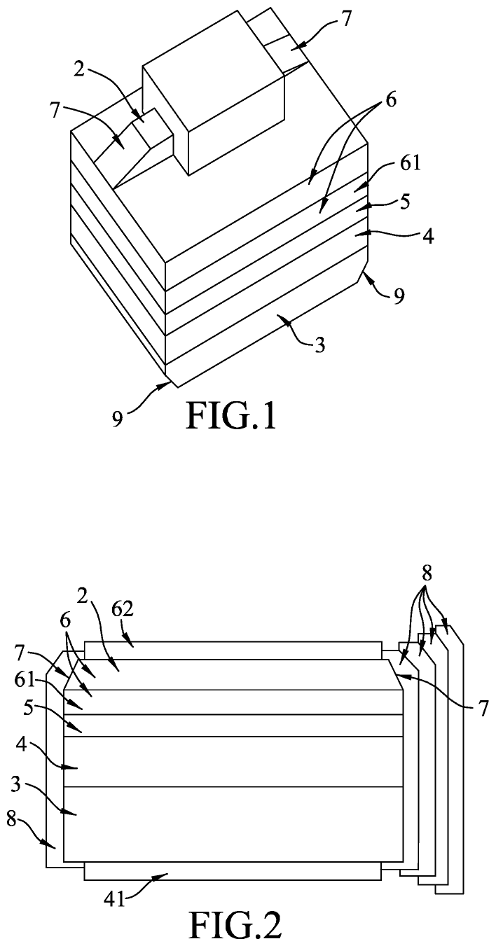

Referring to FIG. 2, an embodiment of a laser diode in accordance with the present disclosure is shown. The laser diode includes a substrate 3, a light-emitting stack disposed on the substrate 3, and a distributed Bragg reflection (DBR) cover layer 8. The light-emitting stack includes an N-type layer 4, an active layer 5, and a P-type layer 6 sequentially formed on the substrate 3. The P-type layer 6 having a ridged member 2 (best shown in FIG. 1). The ridged member 2 has two end faces, each of which includes a first inclined surface 7 inclining with respect to a top surface of the ridged member 2 in an outward and downward direction from the top surface 21. A contact interface between the ridged member 2 and the DBR cover layer 8 includes the first inclined surface 7 at each end face of the ridged member 2. In this embodiment, the active layer 5 is a multi-quantum well (MQW) active layer.

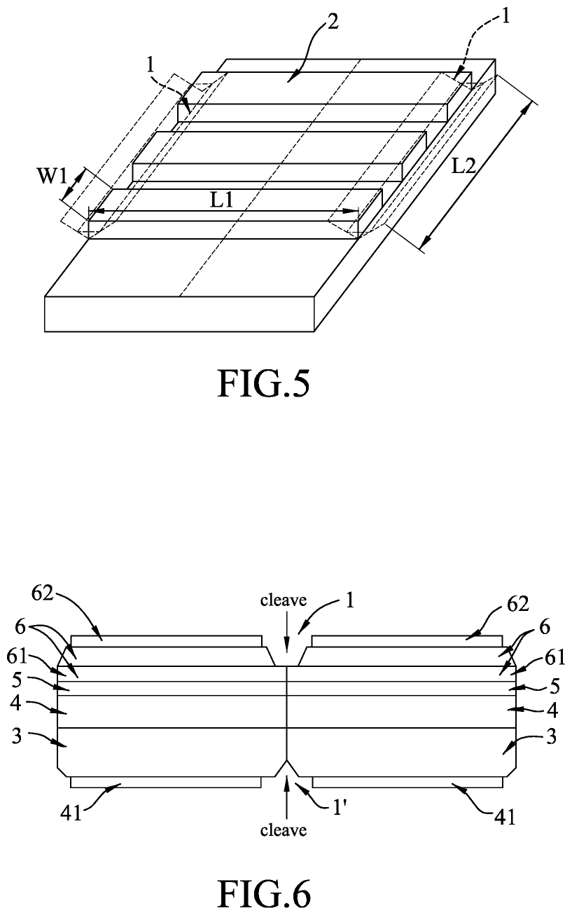

Referring to FIG. 5, the end faces of the ridged member 2 are situated at two ends of the ridged member 2 that are opposite in a lengthwise (L1) direction. The width of the first inclined surface 7 is parallel to the width W1 of the ridged member 2, or the width W1 of the ridged member 2 is the same as that of the first inclined surface 7. The contact interface between the ridged member 2 and the DBR cover layer 8 includes the first inclined surfaces 7. This structure is a one-sided wedge-shaped laser diode. The one-sided wedge-shaped laser diode can alleviate the drawbacks common to conventional Fabry-Pérot cavities having right-angled surfaces, in which poor coverage of the DBR cover layer causes easy breakage when under high stress and in which side-plated DBR cover layers adversely affect the eutectic structure of the laser diode, and thus affects the electrical properties of the laser diode.

In some embodiments, an angle between the first inclined surface 7 and a normal to a bottom surface of the ridged member 2 ranges between 0° and 60°, which ensures that the DBR cover layer 8 properly covers the ridged member 2 and does not peel off easily.

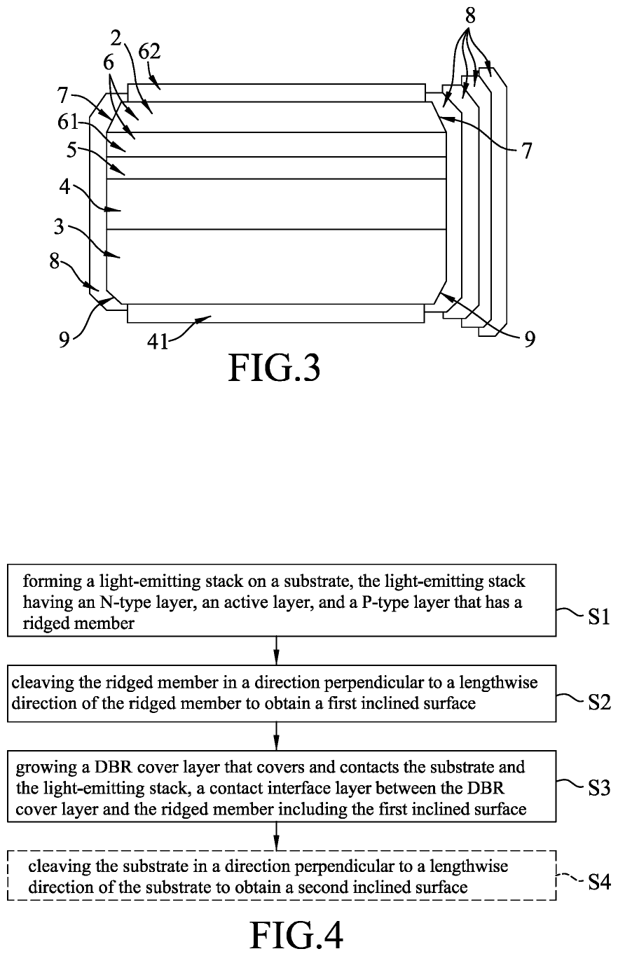

Referring to FIGS. 1 and 3, another embodiment of the laser diode of the disclosure is shown. In this embodiment, the substrate 3 has end faces respectively including second inclined surfaces 9 each of which inclines with respect to a bottom surface of the substrate 3 in an outward and upward direction from the bottom surface 31. The bottom surface 31 is opposite to a top surface where the light-emitting stack grows. The second inclined surfaces 9 are formed at the end faces of the bottom surface 31 that are opposite along the lengthwise direction of the ridged member 2. A contact interface between the substrate 3 and the DBR cover layer 8 includes the second inclined surfaces 9. In this embodiment, the laser diode is a two-sided wedge-shaped laser diode, in which the first inclined surfaces 7 and the second inclined surface 9 cooperatively form the two-sided inclined surface structure. In this structure, the DBR cover layer 8 has a better coverage of the substrate 3 and does not peel off easily, thereby ensuring good electrical conductivity of the laser diode.

In some embodiments, the second inclined surface 9 has an angle with a normal to a top surface of the substrate 3 that ranges between 0° and 60°, which ensures that the DBR cover layer 8 properly covers the substrate 3 and does not peel off easily.

In some embodiments, the first inclined surfaces 7 are disposed on the P-type layer 6. In the process of forming the first inclined surfaces 7, the first inclined surfaces 7 do not extend into the active layer 5.

In some embodiments, the N-type layer 4 includes an N-type metal layer 41. The N-type metal layer 41 is used for connecting the N-type layer 4 and conducting electricity.

In some embodiments, the P-type layer 6 includes a P-type metal layer 62. The P-type metal layer 62 is used for connecting the P-type layer 6 and conducting electricity.

In some embodiments, the P-type layer 6 further includes an upper waveguide layer 61. The upper waveguide layer 61 may be, but not limited to, a P-InGaN layer. The first inclined layers 7 are made by forming grooves 1 (see FIG. 5) on the P-type layer 6 and then cleaving the grooves 1. The groove 1 may be, but not limited to, a V-shaped groove, an arcuated groove, or an inverted trapezoid-shaped groove. The depth of the grooves 1 does not extend to the upper waveguide layer 61. This ensures that the cleavage is not excessive, and that the first inclined surfaces 7 are limited to the P-type layer 6 and does not extend into the active layer 5.

Referring to FIG. 4, an embodiment of a method for making a laser diode according the present disclosure is shown. The method includes steps S1 to S4.

In step S1, a light-emitting stack is formed on the substrate 3. The light-emitting stack has the N-type layer 4, the active layer 5, and the P-type layer 4. The P-type layer 6 is formed with the ridged members 2.

In step S2, the ridged members 2 are cleaved (see FIG. 5) in a direction perpendicular to a lengthwise direction (L1) of the ridged members 2 to obtain first inclined surfaces 7 at two end faces of each ridged member 2 where the ridged member 2 is cleaved.

In step 3, a DBR cover layer 8 that covers and contacts the substrate 3 and the light-emitting stack is grown by using vacuum coating, which may include magnetron sputtering, electron cyclotron resonance (ECR) deposition or chemical vapor deposition. A contact interface between the DBR cover layer 8 and each ridged member 2 includes the first inclined surfaces 7. In this embodiment, the active layer 5 is a multi-quantum well (MQW) active layer. An angle between the first inclined surface 7 and a normal to a bottom surface of the ridged member 2 ranges between 0° and 60°, which ensures that the DBR cover layer 8 properly covers the ridged member 2 and does not peel off easily.

Since the contact interface layer includes the first inclined surface 7, problems such as poor coverage of the DBR and easy breakage when under high stress caused by a right-angled cavity surface and adverse effects on the eutectic structure of the laser diode that affects the electrical properties of the laser diode caused by side-plated DBR are solved.

Another embodiment of the method for making the laser diode further includes step S4 in addition to steps S1, S2, S3. In step S4, the substrate 3 is cleaved after the ridged members 2 are cleaved to obtain the first inclined surfaces 7. In particular, the substrate 3 is cleaved in a direction perpendicular to the lengthwise direction of the ridged member 2 to obtain second inclined surfaces 9 at end faces where the substrate 3 is cleaved. A contact interface between the substrate 3 and the DBR cover layer 8 includes the second inclined surfaces 9. A two-sided wedge-shaped laser diode is thus obtained. In some embodiments, the second inclined surface 9 forms an angle with a normal to a top surface of the substrate 3 that ranges between 0° and 60°, which ensures that the DBR cover layer 8 properly covers the substrate 3 and does not peel off easily.

The two-sided wedge-shaped laser diode obtained from the aforementioned steps has a double inclined surface structure formed cooperatively by the first inclined surfaces 7 and the second inclined surfaces 9 so that the DBR cover layer 8 has a better coverage of the substrate 3 and does not peel off easily, which ensures good electrical conductivity of the laser diode.

Referring to FIG. 5, in some embodiments, cleaving the ridged member 2 includes the steps of forming first grooves 1 on the ridged member 2, and cleaving the middles of the grooves 1 in a direction perpendicular to the lengthwise direction of the ridged member 2. Each first groove 1 may be selected from a V-shaped groove, an arcuated groove, and an inverted trapezoid-shaped groove.

In some embodiments, cleaving the substrate 3 includes the steps of forming a second groove 1′ (see FIG. 6) on the substrate 3, and cleaving the middle of the second groove 1′ in a direction perpendicular to the lengthwise direction of that the ridged member 2. The second groove 1′ may be selected from a V-shaped groove, an arcuated groove arc-shaped, and an inverted trapezoid-shaped groove.

The first and second grooves 1, 1′ extend in a direction perpendicular to the lengthwise direction L1 of the ridged member 2, i.e. L2 is perpendicular to L1. The first and second grooves 1, 1′ may be made by, but not limited to, using a yellow light process and an inductive coupled plasma (ICP) etching process.

Referring back to FIG. 6, in some embodiments, the ridged member 2 and the substrate 3 are formed with differently shaped grooves, and are cleaved so that the two-sided wedge-shaped laser diode having partially beveled edges is obtained. Specifically, for example, an inverted trapezoid-shaped groove 1 is formed in the ridged member 2 and a V-shaped groove 1′ is formed in the substrate 3, and then, the middle of the groove 1 of the ridged member 2 and the middle of the groove 1′ of the substrate 3 are cleaved to obtain inclined end faces. This can increase the range of applicability the method of the present disclosure.

In view of the aforementioned, the method for making the laser diode of the present disclosure not only can ease fabrication of DBR cover layers for laser diodes, but can solve the drawbacks of right-angled cavity surfaces such as poor DBR coverage and easy breakage under high stress, which cause the side-plated DBR to adversely affect the eutectic structure of the laser diode and hence leads to poor electrical properties of the laser diode. In addition, since a portion of the contact interface at the end face is etched to improve the coverage of the DBR, the current density near the contact interface is reduced, and the laser diode is capable of resisting catastrophic optical damage (COD).

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A laser diode, comprising:
a light-emitting stack, said light-emitting stack including an N-type layer, an active layer, and a P-type layer that has a ridged member; and
a distributed Bragg reflection (DBR) cover layer in contact with said light-emitting stack,
wherein
said ridged member has an end face including a first inclined surface that inclines with respect to a top surface of said ridged member in an outward and downward direction from said top surface, and
a contact interface between said ridged member and said DBR cover layer includes said first inclined surface.

2. The laser diode as claimed in claim 1, wherein an angle between said first inclined surface and a normal to a bottom surface of said ridged member ranges between 0° and 60°.

3. The laser diode as claimed in claim 1, further comprising a substrate under said light-emitting stack, said substrate having an end face including a second inclined surface that inclines with respect to a bottom surface of said substrate in an outward and upward direction from said bottom surface, a contact interface between said substrate and said DBR cover layer including said second inclined surface.

4. The laser diode as claimed in claim 3, wherein said second inclined surface has an angle with a normal to a top surface of said substrate that ranges between 0° and 60°.

5. The laser diode as claimed in claim 1, wherein said first inclined surface is located on said P-type layer.

6. The laser diode as claimed in claim 1, wherein said N-type layer includes an N-type metal layer.

7. The laser diode as claimed in claim 1, wherein said P-type layer includes a P-type metal layer.

8. The laser diode as claimed in claim 1, wherein said P-type layer further includes an upper waveguide layer.

9. The laser diode as claimed in claim 8, wherein said upper waveguide layer is a P-InGaN layer.

10. The laser diode as claimed in claim 1, wherein said active layer is a multi-quantum well (MQW) active layer.

11. A method for making a laser diode, comprising:
forming a light-emitting stack, the light-emitting stack having an N-type layer, an active layer, and a P-type layer, the P-type layer being formed with a ridged member;
cleaving the ridged member in a direction perpendicular to a lengthwise direction of the ridged member to obtain a first inclined surface at an end face where the ridged member is cleaved; and
growing a DBR cover layer that covers the light-emitting stack, a contact interface between the DBR cover layer and the ridged member including the first inclined surface.

12. The method as claimed in claim 11, wherein cleaving the ridged member includes:
forming a first groove on the ridged member; and
cleaving the first groove in a direction perpendicular to the lengthwise direction of the ridged member,
wherein the first groove is selected from a V-shaped groove, an arcuated groove, and an inverted trapezoid-shaped groove.

13. The method as claimed in claim 11, wherein the light-emitting stack is formed on a substrate, the method further comprising, after cleaving the ridged member to obtain the first inclined surface, cleaving the substrate in a direction perpendicular to the lengthwise direction of the ridged member to obtain a second inclined surface at an end face where the substrate is cleaved, wherein a contact interface between the substrate and the DBR cover layer includes the second inclined surface.

14. The method as claimed in claim 13, wherein cleaving the substrate includes:
forming a second groove on the substrate; and
cleaving the second groove in a direction perpendicular to the lengthwise direction of the ridged member,
wherein the second groove is selected from a V-shaped groove, an arcuated groove, and an inverted trapezoid-shaped groove.

15. The method as claimed in claim 14, wherein each of the first and second grooves extends in a direction that is perpendicular to the lengthwise direction of the ridged member.

16. The method as claimed in claim 14, wherein each of the first and second grooves extends in a direction that is perpendicular to the lengthwise direction of the ridged member.

17. The method as claimed in claim 14, wherein the first and second grooves are different from each other in shape.
